(19) United States
(12) Patent Application Publication
(10) Pub. No.: US 2013/0175585 A1
(43) Pub. Date: Jul. 11, 2013

(54) Methods of Forming Faceted Stress-Inducing Stressors Proximate the Gate Structure of a Transistor

(71) Applicants: Chung Foong Tan, Dresden (DE); Maciej Wiatr, Dresden (DE); Stephan Kronholz, Dresden (DE); Falong Zhou, Dresden (DE); Ying Hao Hsieh, Dresden (DE)

(72) Inventors: Chung Foong Tan, Dresden (DE); Maciej Wiatr, Dresden (DE); Stephan Kronholz, Dresden (DE); Falong Zhou, Dresden (DE); Ying Hao Hsieh, Dresden (DE)

(73) Assignee: GLOBALFOUNDRIES INC., Grand Cayman (KY)

(21) Appl. No.: 13/348,184

(22) Filed: Jan. 11, 2012

(51) Int. Cl. H01L 21/336; H01L 29/78

(52) U.S. Cl. 257/288; 438/198; 257/E29.255; 257/E21.409

(57) ABSTRACT

Disclosed herein are various methods of forming faceted stress-inducing stressors proximate the gate structure of a transistor. In one example, a method includes forming a first recess in an active region of a semiconducting substrate, forming a first semiconductor material in the first recess and forming a gate structure above the first semiconductor material. In this example, the method includes the additional steps of performing a crystalline orientation-dependent etching process on the first semiconductor material to define a plurality of second recesses proximate the gate structure, wherein each of the second recesses has a faceted edge, and forming a first region of stress-inducing semiconductor material in each of the second recesses, wherein each of the first regions of stress-inducing semiconductor material has a faceted edge that engages a corresponding faceted edge in one of the second recesses.

### BACKGROUND OF THE INVENTION

1. Field of the Invention

Generally, the present disclosure relates to the manufacturing of sophisticated semiconductor devices, and, more specifically, to various methods of forming faceted stress-inducing stressors proximate the gate structure of a transistor.

2. Description of the Related Art

The fabrication of advanced integrated circuits, such as CPU's, storage devices, ASIC's (application specific integrated circuits) and the like, requires the formation of a large number of circuit elements in a given chip area according to a specified circuit layout, wherein field effect transistors (NFET and PFET transistors) represent one important type of circuit element that substantially determines performance of the integrated circuits. During the fabrication of complex integrated circuits using, for instance, MOS technology, millions of transistors, e.g., NFET transistors and/or PFET transistors, are formed on a substrate including a crystalline semiconductor layer. A field effect transistor, irrespective of whether an NFET transistor or a PFET transistor is considered, typically comprises so-called PN junctions that are formed by an interface of highly doped regions, referred to as drain and source regions, with a slightly doped or non-doped region, such as a channel region, disposed between the highly doped source/drain regions.

Device designers are under constant pressure to improve the electrical performance characteristics of semiconductor devices, such as transistors, and the overall performance capabilities of integrated circuit devices that incorporate such devices. One technique that has been and continues to be employed to improve the performance of such transistors is to reduce or scale the channel length of such transistors. As device dimensions have decreased, device designers have resorted to other techniques to improve device performance. One such method involves the use of channel stress engineering techniques on transistors to create a tensile stress in the channel region for NFET transistors and to create a compressive stress in the channel region for PFET transistors. These stress conditions improve charge carrier mobility of the devices—electrons for NFET devices and holes for PFET devices.

One commonly employed stress engineering technique involves the formation of specifically made silicon nitride layers that are selectively formed above appropriate transistors, i.e., a layer of silicon nitride that is intended to impart a tensile stress in the channel region of an NFET transistor would only be formed above the NFET transistors. Such selective formation may be accomplished by masking the PFET transistors and then blanket depositing the layer of silicon nitride, or by initially blanket depositing the layer of silicon nitride across the entire substrate and then performing an etching process to selectively remove the silicon nitride from above the PFET transistors. Conversely, for PFET transistors, a layer of silicon nitride that is intended to impart a compressive stress in the channel region of a PFET transistor is formed above the PFET transistors. The techniques employed in forming such nitride layers with the desired tensile or compressive stress are well known to those skilled in the art. Another stress engineering technique that is typically employed when forming a PFET transistor involves the formation of eptaxially-deposited silicon-germanium source/drain regions, and the formation of an epitaxially-deposited silicon-germanium layer in the channel region of the PFET device. Additional stress engineering techniques that have been performed on NFET transistors includes the formation of silicon-carbon source/drain regions to induce a desired tensile stress in the channel region of an NFET transistor.

In general, it is more beneficial if the stress-inducing material is positioned as close as reasonably possible to the channel region of the transistor. Moreover, to the extent possible, any process flow used in forming such stress-inducing material should be implemented in a manner such that relaxation of the induced stress in the channel region caused by subsequent processing operations is limited.

The present disclosure is directed to various methods of forming faceted stress-inducing stressors proximate the gate structure of a transistor.

### SUMMARY OF THE INVENTION

The following presents a simplified summary of the invention in order to provide a basic understanding of some aspects of the invention. This summary is not an exhaustive overview of the invention. It is not intended to identify key or critical elements of the invention or to delineate the scope of the invention. Its sole purpose is to present some concepts in a simplified form as a prelude to the more detailed description that is discussed later.

Generally, the present disclosure is directed to various methods of forming faceted stress-inducing stressors proximate the gate structure of a transistor. In one example, a method disclosed includes forming a first recess in an active region of a semiconducting substrate, forming a first semiconductor material in the first recess and forming a gate structure above the first semiconductor material. In this example, the method includes the additional steps of performing a crystalline orientation-dependent etching process on the first semiconductor material to define a plurality of second recesses proximate the gate structure, wherein each of the second recesses has a faceted edge, and forming a first region of stress-inducing semiconductor material in each of the second recesses, wherein each of the first regions of stress-inducing semiconductor material has a faceted edge that engages a corresponding faceted edge in one of the second recesses.

In another illustrative example, a method disclosed herein includes forming a first recess in an active region of a semiconducting substrate, forming a first semiconductor material in the first recess, forming a second semiconductor material on the first semiconductor material and forming a gate structure above the second semiconductor material. In this example, the method includes the further steps of performing a crystalline orientation-dependent etching process on at least the second semiconductor material to define a plurality of second recesses proximate the gate structure, wherein each of the second recesses has a faceted edge, and forming a first region of stress-inducing semiconductor material in each of the second recesses, wherein each of the first regions of stress-inducing semiconductor material has a faceted edge that engages a corresponding faceted edge in one of the second recesses.

### BRIEF DESCRIPTION OF THE DRAWINGS

The disclosure may be understood by reference to the following description taken in conjunction with the accompanying drawings, in which like reference numerals identify like elements, and in which:

FIGS. 1A-1G depict various illustrative novel methods described herein for forming faceted stress-inducing stressors proximate the gate structure of a transistor.

While the subject matter disclosed herein is susceptible to various modifications and alternative forms, specific embodiments thereof have been shown by way of example in the drawings and are herein described in detail. It should be understood, however, that the description herein of specific embodiments is not intended to limit the invention to the particular forms disclosed, but on the contrary, the intention is to cover all modifications, equivalents, and alternatives falling within the spirit and scope of the invention as defined by the appended claims.

### DETAILED DESCRIPTION

Various illustrative embodiments of the invention are described below. In the interest of clarity, not all features of an actual implementation are described in this specification. It will of course be appreciated that in the development of any such actual embodiment, numerous implementation-specific decisions must be made to achieve the developers' specific goals, such as compliance with system-related and business-related constraints, which will vary from one implementation to another. Moreover, it will be appreciated that such a development effort might be complex and time-consuming, but would nevertheless be a routine undertaking for those of ordinary skill in the art having the benefit of this disclosure.

The present subject matter will now be described with reference to the attached figures. Various structures, systems and devices are schematically depicted in the drawings for purposes of explanation only and so as to not obscure the present disclosure with details that are well known to those skilled in the art. Nevertheless, the attached drawings are included to describe and explain illustrative examples of the present disclosure. The words and phrases used herein should be understood and interpreted to have a meaning consistent with the understanding of those words and phrases by those skilled in the relevant art. No special definition of a term or phrase, i.e., a definition that is different from the ordinary and customary meaning as understood by those skilled in the art, is intended to be implied by consistent usage of the term or phrase herein. To the extent that a term or phrase is intended to have a special meaning, i.e., a meaning other than that understood by skilled artisans, such a special definition will be expressly set forth in the specification in a definitional manner that directly and unequivocally provides the special definition for the term or phrase.

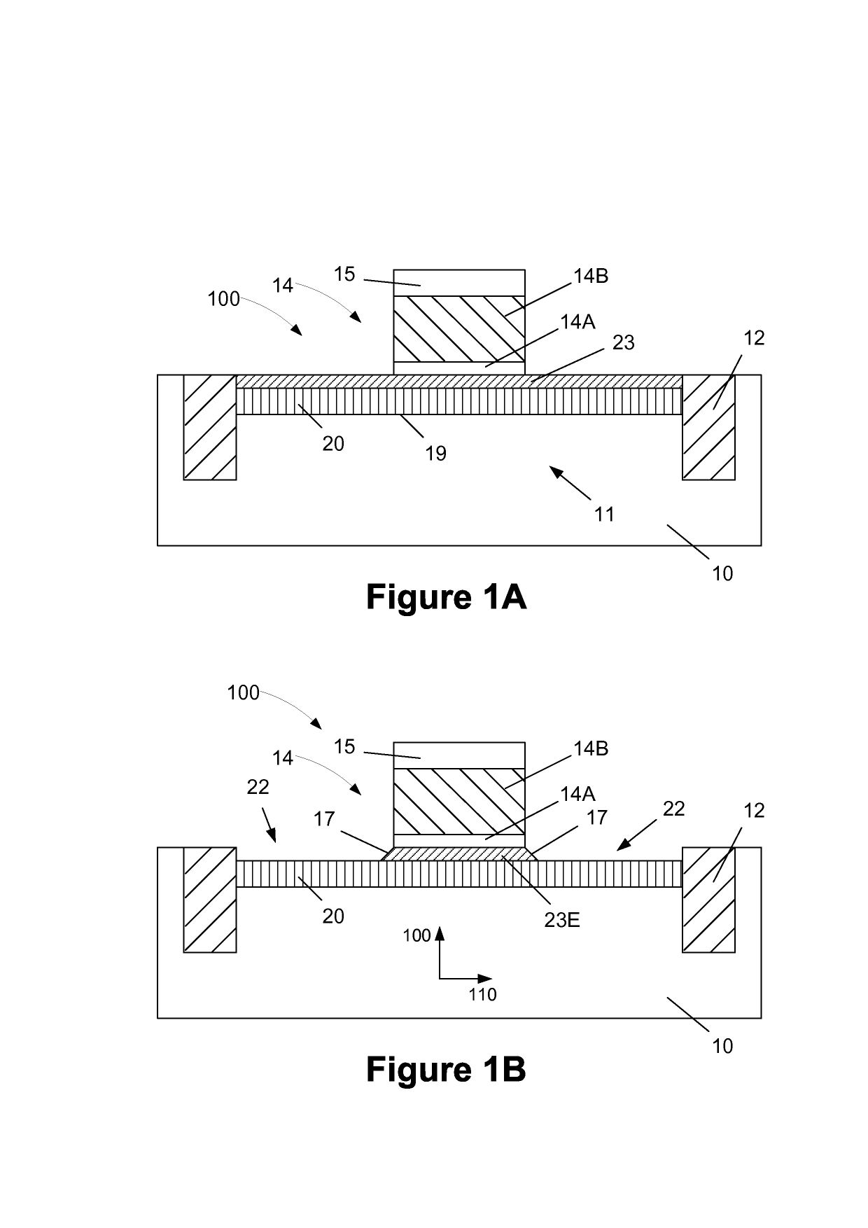

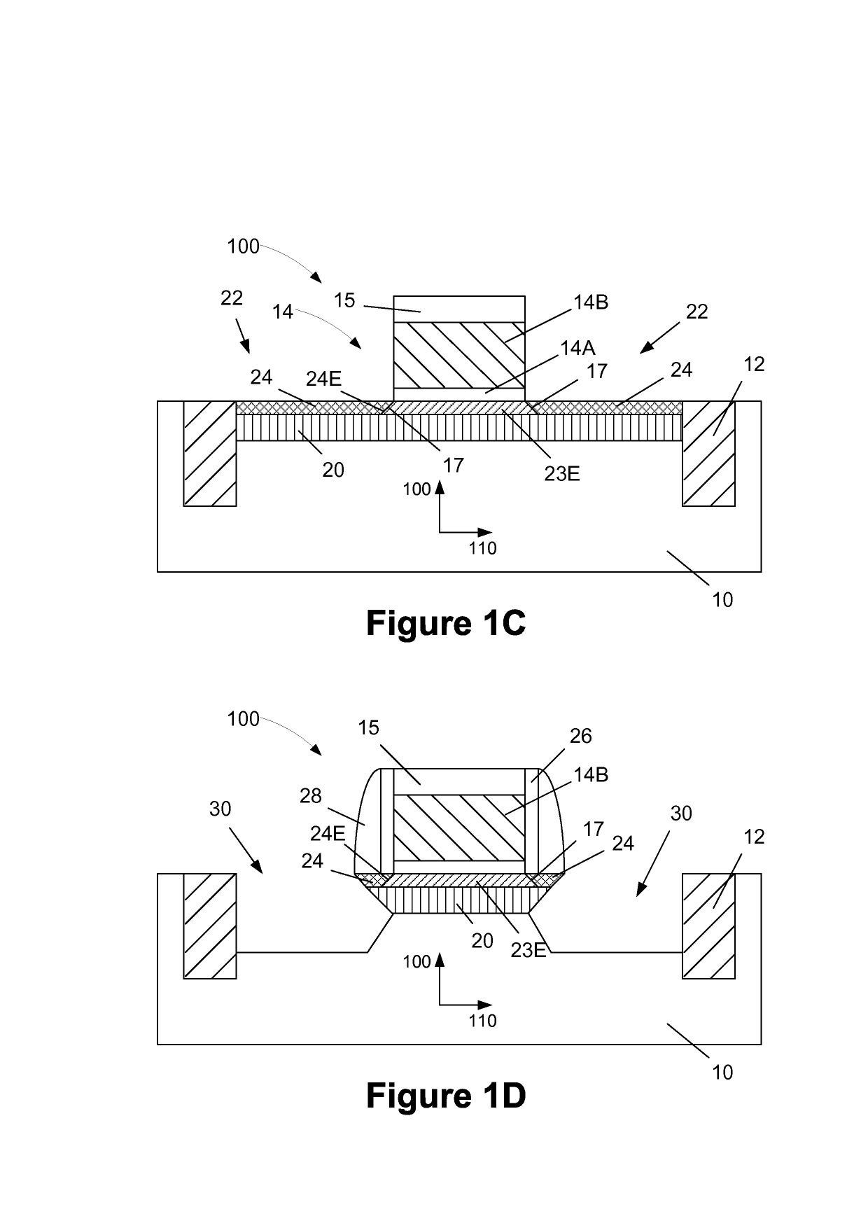

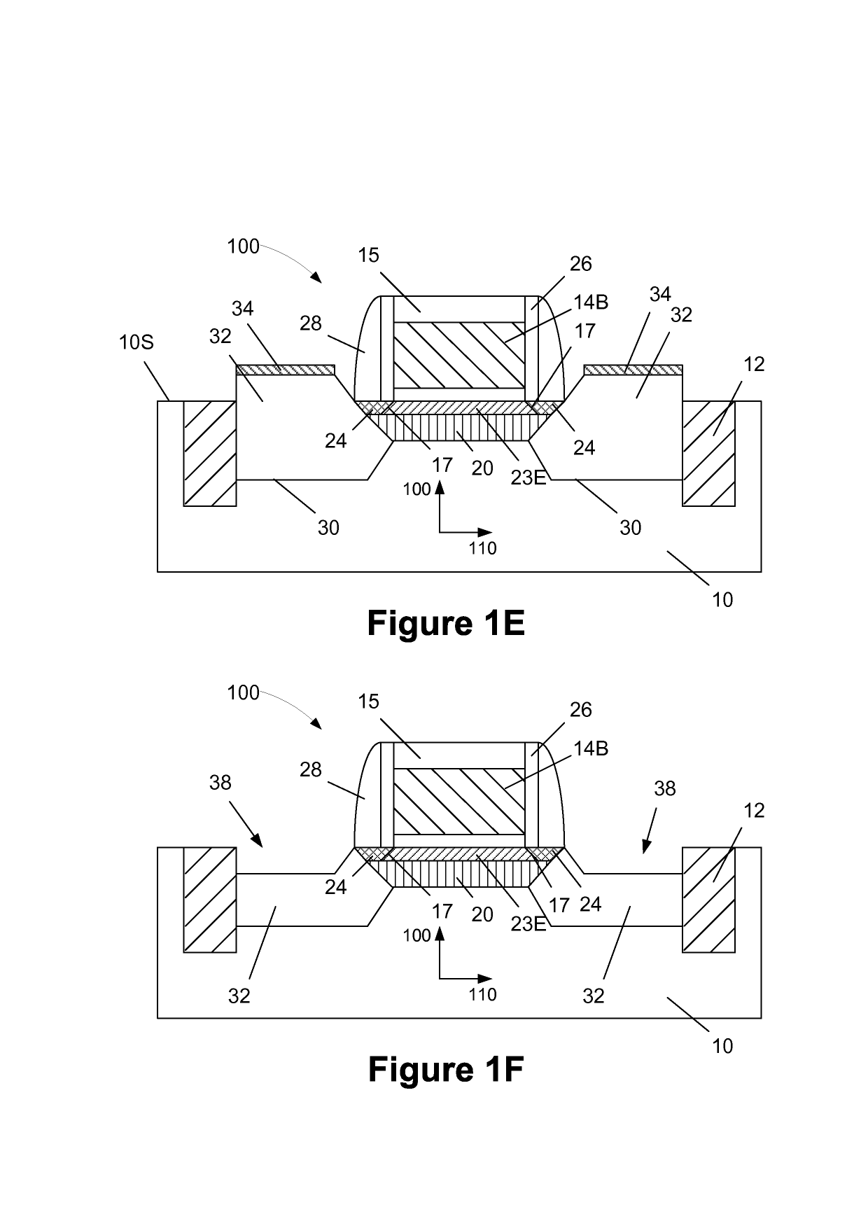

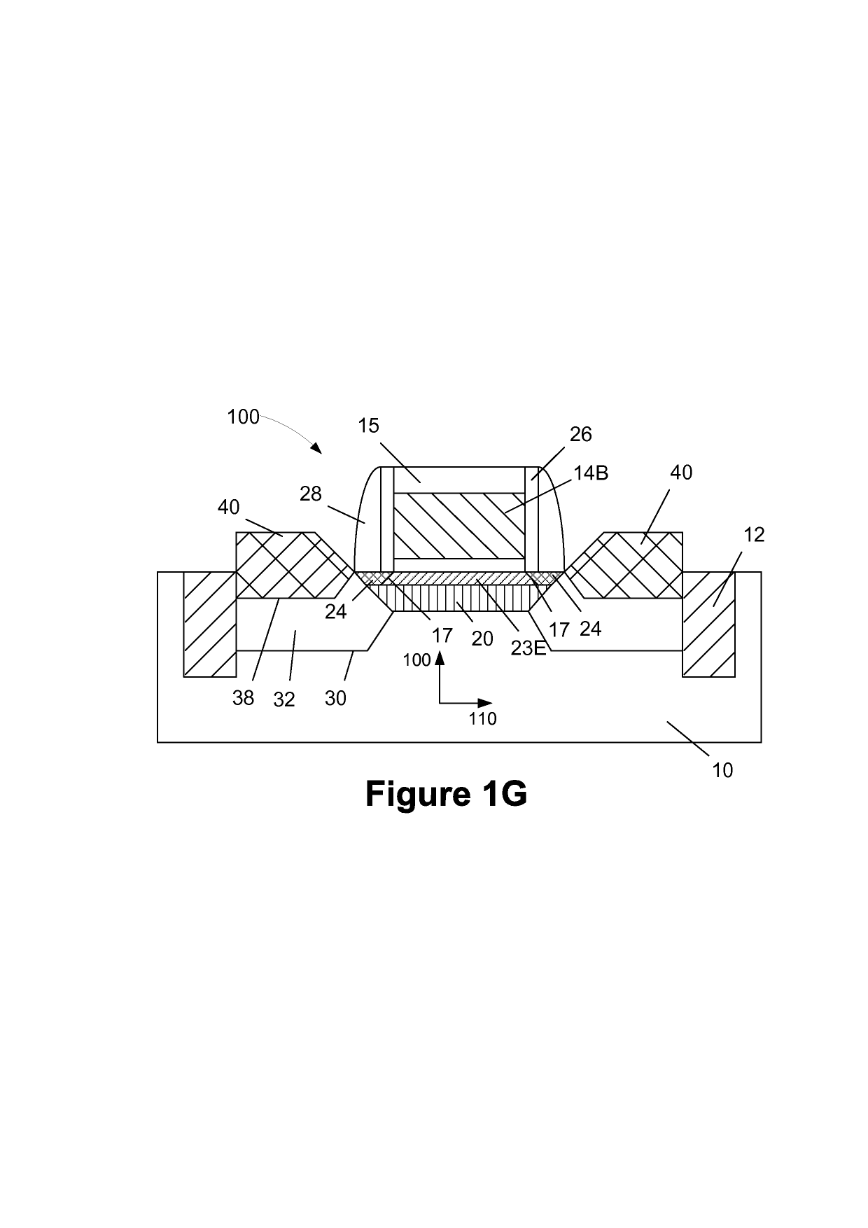

The present disclosure is directed to various methods of forming faceted stress-inducing stressors proximate the gate structure of a transistor. As will be readily apparent to those skilled in the art upon a complete reading of the present application, the present methods and systems are applicable to a variety of technologies, e.g., PFET, NFET, CMOS, etc., and they are readily applicable to a variety of devices, including, but not limited to, ASICs, logic devices, memory devices, etc. With reference to FIGS. 1A-1G, various illustrative embodiments of the methods disclosed herein will now be described in more detail.

FIG. 1A is a simplified view of an illustrative transistor 100 at an early stage of manufacturing. The transistor 100 may be either an NFET transistor or a PFET transistor.

The transistor 100 is formed in and above an active region of a semiconducting substrate 10 that is defined by an illustrative trench isolation structure 12 formed in the substrate 10. The substrate 10 may have a variety of configurations, such as the depicted bulk silicon configuration. The substrate 10 may also have a silicon-on-insulator (SOI) configuration that includes a bulk silicon layer, a buried insulation layer and an active layer, wherein semiconductor devices are formed in and above the active layer. Thus, the terms substrate or semiconducting substrate should be understood to cover all semiconductor structures. The substrate 10 may also be made of materials other than silicon.

Several process operations have been performed on the transistor 100 at the point of fabrication depicted in FIG. 1A. Initially, illustrative isolation structures 12 were formed in the substrate 10 to thereby define an active region 11. Then, an etching process was performed to define a recess or cavity 19 in the active region 11. Next, a layer of semiconductor material 20 is formed in the cavity 19. The semiconductor material 20 may be comprised of a variety of materials, such as silicon, germanium, etc., and its thickness may vary depending on the particular application. Moreover, the semiconductor material 20 may, in some applications, be doped with an appropriate dopant (N or P depending upon the type of transistor being manufactured) or it may be undoped. In one illustrative embodiment, the semiconductor material 20 may be a doped layer of silicon/germanium having a thickness that may range from about 6-10 nm that is formed by performing an epitaxial deposition process. The semiconductor material 20 may be manufactured in such a way so as to impart a desired stress (tensile for an NFET transistor or compressive for a PFET transistor) on what will become the channel region of the transistor 100. The techniques used to form the semiconductor material 20 such that it has the desired stress properties are well known to those skilled in the art.

With continuing reference to FIG. 1A, in some embodiments disclosed herein, a second layer of semiconductor material 23 may be formed above the first layer of semiconductor material 20. The semiconductor material 23 may be comprised of a variety of materials, such as silicon, etc., and its thickness may vary depending on the particular application. Moreover, the semiconductor material 23 may, in some applications, be doped with an appropriate dopant (N or P depending upon the type of transistor being manufactured) or it may be undoped. In one illustrative embodiment, the semiconductor material 23 may be a doped layer of silicon having a thickness that may range from about 1-2 nm that is formed by performing an epitaxial deposition process. The semiconductor material 23 may also be manufactured in such a way so as to impart a desired stress (tensile for an NFET transistor or compressive for a PFET transistor) on what will become the channel region of the transistor 100. It should be understood that the second semiconductor material 23 is not required in all applications of the inventions disclosed herein. Thus, the term “semiconductor material” when used in the claims should be understood to cover any type of semiconductor material and any number of layers of such semiconductor materials. It also should be understood that the relative size of the various features and layers of material shown in the drawing are not to scale and that the relative sizes of some features or layers have been increased to facilitate the discussion and explanations set forth herein.

Still with continuing reference to FIG. 1A, the transistor 100 includes a schematically depicted gate electrode structure 14 that typically includes an illustrative gate insulation layer 14A and an illustrative gate electrode 14B. A gate cap layer 15 is formed above the gate electrode 14B. The gate insulation layer 14A may be comprised of a variety of different materials, such as, for example, silicon dioxide, a so-called high-k (k greater than 10) insulation material, etc. Similarly, the gate electrode 14B may also be of a material such as polysilicon or amorphous silicon, or it may be comprised of one or more metal layers that act as the gate electrode 14B. As will be recognized by those skilled in the art after a complete reading of the present application, the gate electrode structure 14 of the transistor 100 depicted in the drawings, i.e., the gate insulation layer 14A and the gate electrode 14B, is intended to be representative in nature. That is, the gate electrode structure 14 may be comprised of a variety of different materials and it may have a variety of configurations, and the gate electrode structure 14 may be made using either so-called “gate-first” or “gate-last” techniques. For ease of explanation, the illustrative transistor 100 will be depicted as having a polysilicon gate electrode 14B, however, the present invention should not be considered as limited to such an illustrative embodiment. In some cases, as shown in FIG. 1D, a relatively thin liner layer 26 and/or spacer(s) 28, e.g., silicon dioxide or silicon nitride, may be formed adjacent the gate structure 14. Thus, when it is stated in this specification or the claims that an etching process is performed to define recesses, as described more fully below, in the substrate 10 “proximate” the gate electrode structure, that terminology should be understood to cover situations where a liner and/or spacer(s) is not formed adjacent the gate structure 14 as well as situations in which such a liner and/or spacer(s) are present. Additionally, to the extent that the claims use terms like “first semiconductor material” or “second semiconductor material,” such terminology is not meant to imply that the “first semiconductor material” was literally the first semiconductor material formed on the device and the use of such terminology should not be understood as mandating any particular order of formation unless such order of formation is clear from the express language of the claims. Although not depicted in the drawings, at the point of fabrication depicted in FIG. 1A, so-called halo implant regions (not shown) have been formed in the substrate 10, typically by performing an angled ion implant process (with a P-type dopant for an NFET transistor and with an N-type dopant for a PFET transistor).

Next, as shown in FIG. 1B, a crystalline orientation-dependent etching process is performed on the second semiconductor material 23 to define recesses 22 in the substrate 10 proximate the gate structure 14. In some cases, such as where there are no liners or spacers formed on the gate structure 14, the recesses may be effectively self-aligned with the gate structure. In one illustrative embodiment, the etching process is performed using a crystalline orientation-dependent etchant which has an etch rate that varies based upon the crystalline structure of the silicon substrate 10. Examples of such crystalline orientation-dependent etchants include TMAH (tetra methyl ammonium hydroxide), ammonium hydroxide, KOH (Potassium Hydroxide), EDP (Ethylene-Diamene-Pyrocatechol), etc. When etching crystalline silicon, TMAH exhibits a higher etch rate in the direction defined by the “110” plane than it does in the direction defined by the “100” plane, which are both depicted in FIG. 1B. Importantly, the crystalline orientation-dependent etching process results in an etched layer 23E of the second semiconductor material that has a faceted surface 17 that terminates on the “111” plane of the substrate 10, e.g., at an angle of about 54.7 degrees (measured from a reference horizontal surface), although an angle within the range of about 50-60 degrees would also be acceptable. This faceted surface 17 provides a good interface for a future epitaxial deposition process, e.g., silicon/germanium where higher concentrations of germanium may be incorporated without causing any significant dislocations or stress relaxation. Additionally, the faceted surface 17 formed by performing a crystalline orientation-dependent etching process will usually have a smoother surface than could be achieved by performing an anisotropic etching process. In some applications, the semiconductor materials 20, 23 may be selected such that they may be selectively etched with respect to one another. In other applications, the etching process performed to define the recesses 22 may simply be a timed etching process. In one illustrative example, the etching process results in the recesses 22 having a depth of about 1-3 nm. In cases where the second semiconductor material 23 is not present, the recesses 22 may be formed in the first semiconductor material 20 by performing the crystalline orientation-dependent etching process.

Next, as shown in FIG. 1C, a stress-inducing layer of semiconductor material 24 is formed in the cavities 22. The stress-inducing semiconductor material 24 has a faceted edge 24E that forms on the faceted edge 17 of the second semiconductor material 23E. The stress-inducing semiconductor material 24 may be comprised of a variety of materials, such as silicon/germanium, silicon/carbon, etc., and its thickness may vary depending on the particular application. Moreover, the stress-inducing semiconductor material 24 maybe doped with an appropriate dopant (N or P depending upon the type of transistor being manufactured) or it may be undoped. In some cases, where the stress-inducing semiconductor material 24 is comprised of silicon/germanium, the germanium content may be as high as about 37%. In one particular example, the stress-inducing semiconductor material 24 may be doped as it is being formed, in situ, with a dopant level that would generally correspond to an extension implant for the transistor 100. That is, in one illustrative embodiment, the stress-inducing semiconductor material 24 may be an in situ doped layer of silicon/germanium that is doped with an extension implant level of doping. In this illustrative example, the thickness of the stress-inducing semiconductor material 24 may range from about 1-3 nm. The stress-inducing semiconductor material 24 may be manufactured in such a way so as to impart a desired stress (tensile for an NFET transistor or compressive for a PFET transistor) on what will become the channel region of the transistor 100. The techniques used to form the stress-inducing semiconductor material 24 such that it has the desired stress properties are well known to those skilled in the art.

Next, as shown in FIG. 1D, in one illustrative embodiment, so-called sigma-shaped cavities 30 are formed in the substrate 10. The depth of the cavities 30 may vary depending on the particular application. In one illustrative embodiment, the sigma shaped cavities 30 may be formed by performing an initial dry anisotropic etching process to define an initial trench and thereafter performing a crystalline orientation-dependent etching process to complete the formation of the sigma-shaped cavities 30. The crystalline orientation-dependent etching process may be performed using any of the crystalline orientation-dependent etchants described above. Of course, after a complete reading of the present application, those skilled in the art will readily appreciate that the inventions disclosed herein may be employed with transistors 100 that do not have the illustrative sigma-shaped cavities 30 depicted in the drawings, i.e., the transistor 100 may have traditional source/drain regions that may be formed without forming any cavity or cavities having a different configuration from the depicted sigma-shaped cavities 30.

FIG. 1E depicts the transistor 100 after an epitaxial deposition process is performed to form illustrative epitaxial silicon/germanium regions 32 in the sigma-shaped cavities 24A (FIG. 1D). In the depicted example, the epitaxial silicon/germanium regions 32 have an overfill portion that extends above the surface 10S of the substrate 10. The epitaxial silicon/germanium regions 32 may be formed by performing well-known epitaxial deposition processes. The epitaxial silicon/germanium regions 32 may be manufactured in such a way so as to impart a desired stress (tensile for an NFET transistor or compressive for a PFET transistor) on what will become the channel region of the transistor 100. The techniques used to form the epitaxial silicon/germanium regions 32 such that it has the desired stress properties are well known to those skilled in the art. Also depicted in FIG. 1E is an illustrative silicon cap layer 34 that may be formed by performing another epitaxial deposition process. In one example, the silicon cap layer 34 may have a thickness of about 10-20 nm, although its thickness may vary depending upon the particular application.

Next, as shown in FIG. 1F, in some applications disclosed herein, a second sigma-shaped cavity 38 is formed in the silicon/germanium regions 32. In these applications, the formation of the silicon cap layer 34 shown in FIG. 1E may be omitted. The second sigma-shaped cavity 38 may be formed using the same etching techniques described above with respect to the formation of the first sigma-shaped cavities 30 (FIG. 2D). The depth of the second sigma-shaped cavities 38 may likewise vary depending on the particular application.

Then, as shown in FIG. 1G, one or more semiconductor materials 40 are formed in the second sigma-shaped cavities 38. The semiconductor material 40 may take a variety of forms. For example, the semiconductor material may be comprised of silicon/germanium having a relatively low germanium concentration, e.g., 7-15%, or it may be a cap layer comprised of pure silicon. The semiconductor material 40 may be formed by performing one or more epitaxial deposition processes wherein various dopant materials may be introduced in situ. If desired, the semiconductor material 40 may also be formed so as to impart the desired stress on the transistor.

The particular embodiments disclosed above are illustrative only, as the invention may be modified and practiced in different but equivalent manners apparent to those skilled in the art having the benefit of the teachings herein. For example, the process steps set forth above may be performed in a different order. Furthermore, no limitations are intended to the details of construction or design herein shown, other than as described in the claims below. It is therefore evident that the particular embodiments disclosed above may be altered or modified and all such variations are considered within the scope and spirit of the invention. Accordingly, the protection sought herein is as set forth in the claims below.

1. A method, comprising:
forming a first recess in an active region of a semiconducting substrate;
forming a first semiconductor material in said first recess;
forming a gate structure above said first semiconductor material;
performing a crystalline orientation-dependent etching process on said first semiconductor material to define a plurality of second recesses proximate said gate structure, wherein each of said second recesses has a faceted edge;
forming a first region of stress-inducing semiconductor material in each of said second recesses, wherein each of said first regions of stress-inducing semiconductor material has a faceted edge that engages a corresponding faceted edge in one of said second recesses; and
performing at least one additional etching process to form a plurality of sigma-shaped cavities in said substrate, said at least one additional etching process removing a portion, but not all, of said first region of stress-inducing semiconductor material formed in each of said plurality of second recesses.

2. The method of claim 1, further comprising, prior to performing said crystalline orientation-dependent etching process, forming at least one of a liner layer or a sidewall spacer adjacent said gate structure.

3. The method of claim 1, wherein said crystalline orientation-dependent etching process is performed using one of the following: TMAH (tetra methyl ammonium hydroxide), ammonium hydroxide, KOH (Potassium Hydroxide), EDP (Ethylene-Diamene-Pyrocatechol).

4. The method of claim 1, wherein said faceted edge of each of said second recesses lies in a 111 crystalline plane of at least said first semiconductor material.

5. The method of claim 1, wherein each of said second recesses has a depth that ranges from 1-3 nm.

6. The method of claim 1, wherein said faceted edge of each of said second recesses is self-aligned with respect to an exposed sidewall of a gate electrode comprising said gate structure.

7. The method of claim 1, wherein said gate structure comprises a gate insulation layer and a gate electrode positioned above said gate insulation layer.

8. The method of claim 1, wherein forming said first semiconductor material in said first recess comprises performing an epitaxial deposition process to form a first semiconductor material comprised of silicon/germanium or silicon in said first recess.

9. The method of claim 1, wherein forming said first region of stress-inducing semiconductor material comprises performing an epitaxial deposition process to form said first region of stress-inducing semiconductor material such that it exhibits either a tensile or compressive stress.

10. The method of claim 1, wherein forming said first region of stress-inducing semiconductor material comprises performing an epitaxial deposition process to form said first region of stress-inducing material comprised of silicon/germanium or silicon in said plurality of second recesses.

11. (canceled)

12. The method of claim 1, further comprising forming a second region of stress-inducing semiconductor material in each of said sigma-shaped cavities.

13. The method of claim 12, further comprising forming a second sigma-shaped cavity in said second region of stress-inducing semiconductor material.

14. The method of claim 13, further comprising forming a third semiconductor material in said second sigma-shaped cavity.

15. A method, comprising:
forming a first recess in an active region of a semiconducting substrate;
forming a first semiconductor material in said first recess;
forming a second semiconductor material on said first semiconductor material;
forming a gate structure above said second semiconductor material;
performing a crystalline orientation-dependent etching process on at least said second semiconductor material to define a plurality of second recesses proximate said gate structure, wherein each of said second recesses has a faceted edge;
forming a first region of stress-inducing semiconductor material in each of said second recesses, wherein each of said first regions of stress-inducing semiconductor material has a faceted edge that engages a corresponding faceted edge in one of said second recesses; and
performing at least one additional etching process to form a plurality of sigma-shaped cavities in said substrate, said at least one additional etching process removing a portion, but not all, of said first region of stress-inducing semiconductor material formed in each of said plurality of second recesses.

16. The method of claim 15, further comprising, prior to performing said crystalline orientation-dependent etching process, forming at least one of a liner layer or a sidewall spacer adjacent said gate structure.

17. The method of claim 15, wherein forming said first semiconductor material in said first recess comprises performing a first epitaxial deposition process to form a first semiconductor material comprised of silicon/germanium in said first recess and wherein forming said second semiconductor material on said first semiconductor material comprises performing a second epitaxial deposition process to form a second semiconductor comprised of silicon on said first semiconductor material.

18. The method of claim 15, wherein forming said first region of stress-inducing semiconductor material comprises performing an epitaxial deposition process to form said first region of stress-inducing semiconductor such that it exhibits either a tensile or compressive stress.

19. The method of claim 15, wherein forming said first region of stress-inducing semiconductor material comprises performing an epitaxial deposition process to form said first region of stress-inducing material comprised of silicon/germanium or silicon in said plurality of second recesses.

20. (canceled)

21. The method of claim 15, further comprising forming a second region of stress-inducing semiconductor material in each of said sigma-shaped cavities.

22. The method of claim 21, further comprising forming a second sigma-shaped cavity in said second region of stress-inducing semiconductor material.

23. The method of claim 22, further comprising forming a third semiconductor material in said second sigma-shaped cavity.

24. The method of claim 15, wherein said faceted edge of each of said second recesses lies in a 111 crystalline plane of at least said first semiconductor material.

25. (canceled)

26. (canceled)

27. The method of claim 1, wherein forming said first semiconductor material in said first recess comprises forming a first stress-inducing material.

28. The method of claim 15, wherein forming said first semiconductor material in said first recess comprises forming a first stress-inducing material, and wherein forming said second semiconductor material in said first recess comprises forming a second stress-inducing material.

29. A method, comprising:
forming a first recess in an active region of a semiconducting substrate;
forming a semiconductor material in said first recess;
forming a gate structure comprising a gate dielectric layer and a gate electrode above said first semiconductor material;
performing a crystalline orientation-dependent etching process on said semiconductor material to define a plurality of second recesses proximate said gate structure, wherein each of said second recesses has a faceted edge that is substantially self-aligned with an exposed sidewall of said gate electrode;
forming a first region of stress-inducing semiconductor material in each of said second recesses, wherein each of said first regions of stress-inducing semiconductor material has a faceted edge that engages a corresponding faceted edge in one of said second recesses;
after forming said first regions of stress-inducing semiconductor material, forming at least one spacer element on said exposed sidewalls of said gate electrode;
forming a plurality of first sigma-shaped cavities in said substrate that are substantially self-aligned with said at least one spacer element, wherein forming each of said plurality of first sigma-shaped cavities comprises removing first a portion of each of said first regions of stress-inducing semiconductor material while leaving a second portion of each of said first regions positioned below said at least one spacer element; and
forming a second region of stress-inducing semiconductor material in each of said first sigma-shaped cavities.

30. The method of claim 29, further comprising:
forming a second sigma-shaped cavities in each of said first regions of stress-inducing semiconductor material, wherein each of said second sigma-shaped cavities are substantially self-aligned with said at least one spacer element; and
forming a third region of stress-inducing semiconductor material in each of said second sigma-shaped cavities.
